(19) United States
(12) Patent Application Publication
(10) Pub. No.: US 2024/0413819 A1
(43) Pub. Date: Dec. 12, 2024

(54) RADIO FREQUENCY SWITCH CIRCUIT

(71) Applicant: SAMSUNG ELECTRO-MECHANICS CO., LTD., Suwon-si (KR)

(72) Inventors: Byeonghak JO, Suwon-si (KR); Wonsun HWANG, Suwon-si (KR); Shinhaeng HEO, Suwon-si (KR)

(73) Assignee: SAMSUNG ELECTRO-MECHANICS CO., LTD., Suwon-si (KR)

(21) Appl. No.: 18/538,446

(22) Filed: Dec. 13, 2023

(30) Foreign Application Priority Data
Jun. 8, 2023 (KR) 10-2023-0073431

(51) Int. Cl. H03K 17/56; H03K 5/01

(52) U.S. Cl. CPC H03K 17/56; H03K 5/01

(57) ABSTRACT

A radio frequency (RF) switch circuit that outputs signals input through first and second input ports to an output port is provided. The RF switch circuit includes a first series switch that outputs the signal input through the first input port; a first shunt switch connected to the first input port; a first attenuation circuit connected between the first shunt switch and ground and attenuating the signal output from the first input port to the output port; a detector that detects a magnitude of a signal output to the output port and generates a first control signal based on the magnitude of the detected signal; and a switch control circuit that controls the first series switch, the first shunt switch, and the first attenuation circuit with the first control signal and a second control signal to select a signal path between the first input port and the output port.

### CROSS-REFERENCE TO RELATED APPLICATIONS

This application claims the benefit under 35 USC 119(a) of Korean Patent Application No. 10-2023-0073431 filed on Jun. 8, 2023, in the Korean Intellectual Property Office, the entire disclosure of which is incorporated herein by reference for all purposes.

### BACKGROUND

### 1. Field

The following description relates to a radio frequency (RF) switch circuit.

### 2. Description of the Background

As the spread of a 5th generation network increases in a wireless communication system, a long term evolution (LTE) network, a 2nd generation network and the 5th generation network are being integrated into a single mobile phone system. As radio frequency (RF) components of various frequency bands are integrated, the implementation of RF switches that select paths of RF signals is also increasing. The RF switch may select a signal of an input frequency band and output the selected signal to a power amplifier.

Typically, the power amplifier may have an operating range of a signal magnitude, and if a signal exceeding the operating range is input, damage may occur to the power amplifier. To prevent such damage, an over voltage protection (OVP) or over current protection (OCP) circuit may be added inside the power amplifier.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a radio frequency (RF) switch circuit configured to output a first signal input through a first input port to an output port, and configured to output a second signal input through a second input port to the output port, the RF switch circuit includes a first series switch configured to output the first signal input through the first input port to the output port; a first shunt switch connected to the first input port; a first attenuation circuit connected between the first shunt switch and a ground, and configured to attenuate the first signal output from the first input port to the output port; a detector configured to detect a magnitude of one of the first signal and the second signal output to the output port, and generate a first control signal based on the magnitude of the detected signal; and a switch control circuit configured to control the first series switch, the first shunt switch, and the first attenuation circuit based on the first control signal and a second control signal to select a first signal path between the first input port and the output port.

The first attenuation circuit may include a first switch connected between the first shunt switch and the ground; and a first resistor connected between the first shunt switch and the ground, wherein the switch control circuit may be configured to determine a turn-on operation or a turn-off operation of the first series switch, the first shunt switch, and the first switch based on the first control signal and the second control signal.

The RF circuit may further include a second series switch configured to output the signal input through the second input port to the third port; a second shunt switch connected to the second input port; and a second attenuation circuit connected between the second shunt switch and the ground and configured to attenuate the signal output from the second input port to the output port, wherein the switch control circuit is configured to select the first signal path between the first input port and the output port or a second signal path between the second input port and the output port based on a value of the second control signal, and control the second series switch, the second shunt switch, and the second attenuation circuit based on the first control signal and the second control signal.

The second attenuation circuit may include a second switch connected between the second shunt switch and the ground; and a second resistor connected between the second shunt switch and the ground, wherein the switch control circuit may be configured to determine a turn-on operation or a turn-off operation of the second series switch, the second shunt switch, and the second switch based on the first control signal and the second control signal.

The detector may include a reference voltage selector configured to select a reference voltage based on the second control signal; and a comparator configured to compare a first voltage corresponding to a magnitude of the first signal or the second signal output to the output port with the reference voltage, and generate the first control signal to have a first value when the first voltage is less than the reference voltage, and to have a second value when the first voltage is greater than or equal to the reference voltage.

The second control signal may have a first value indicating signal path selection between the first input port and the output port, and a second value indicating signal path selection between the second input port and the output port, and the reference voltage selector may be configured to store different reference voltages respectively corresponding to the first value of the second control signal and the second value of the second control signal, and provide the selected reference voltage corresponding to the value of the input second control signal to the comparator.

When the second control signal has the first value and the first control signal has the second value, the switch control circuit may be configured to control the first series switch to be in a turned on state, control the second series switch to be in a turned off state, control the first shunt switch, the second shunt switch, and the second switch to be in a turned on state, and control the first switch to be in a turned off state.

When the second control signal has the second value and the first control signal has the second value, the switch control circuit may be configured to control the second series switch to be in a turned on state, control the first series switch to be in a turned off state, control the first shunt switch, the second shunt switch, and the first switch to be in a turned on state, and control the second switch to be in a turned off state.

When the second control signal has the first value and the first control signal has the first value, the switch control circuit may be configured to control the first series switch to be in a turned on state, control the second series switch to be in a turned off state, control the first shunt switch to be in a turned off state, and control the second shunt switch and the second switch to be in a turned on state.

When the second control signal has the second value and the first control signal has the first value, the switch control circuit may be configured to control the second series switch to be in a turned on state, control the first series switch to be in a turned off state, control the second shunt switch to be in a turned off state, and control the first shunt switch and the first switch to be in a turned on state.

In a general aspect, a radio frequency (RF) switch includes a first input port configured to receive a first signal; a first input port configured to receive a first signal; an output port; a first switch part configured to output the first signal to the output port; a second switch part configured to output the second signal to the output port; a first attenuation circuit configured to attenuate the first signal output to the output port; a second attenuation circuit configured to attenuate the second signal output to the output port; a detector configured to detect a magnitude of one of the first signal and the second signal output to the output port and generate a first control signal based on the magnitude of the detected signal; and a switch control circuit configured to control the first switch part, the second switch part, the first attenuation circuit, and the second attenuation circuit based on the first control signal and a second control signal to select one of a first signal path between the first input port and the output port, and a second signal path between the second input port and the output port.

The first switch part may include a first series switch connected between the first input port and the output port; and a first shunt switch connected between the first input port and a ground, the second switch part may include a second series switch connected between the second input port and the output port; and a second shunt switch connected between the second input port and the ground, the first attenuation circuit may include a first switch connected between the first shunt switch and the ground; and a first resistor connected between the first shunt switch and the ground, and the second attenuation circuit may include a second switch connected between the second shunt switch and the ground; and a second resistor coupled between the second shunt switch and the ground.

The detector may include a reference voltage selector configured to select a reference voltage based on the second control signal; and a comparator configured to generate the first control signal to have a first value when a first voltage corresponding to the magnitude of the one of the first signal and the second signal output to the output port is less than the reference voltage, and to have a second value when the first voltage is greater than or equal to the reference voltage.

The second control signal may have a first value to select the first signal path and a second value to select the second signal path, and the reference voltage selector may be configured to select the reference voltage when the second control signal has a first value, and may be configured to select the reference voltage when the second control signal has a second value different from the first value, and provide the selected reference voltage to the comparator.

The switch control circuit may be configured to control a turn-on operation or a turn-off operation of the first series switch and the second series switch based on the value of the second control signal, and control a turn-on operation or a turn-off operation of the first shunt switch, the second shunt switch, the first switch, and the second switch based on the value of the first control signal and the value of the second control signal, the second control signal may have a first value to select the first signal path and a second value to select the second signal path, and the first control signal may have a first value and a second value different from the first value based on the magnitude of the signal output to the output port.

In a general aspect, a radio frequency (RF) switch includes a first input port; a second input port; an output port; a first switch part, including a first series switch and a first shunt switch, and configured to receive a first signal from the first input port; a second switch part, including a second series switch and a second shunt switch, and configured to receive a second signal from the second input port; a first attenuation circuit, connected between the first switch part and a ground, and comprising a first switch and a resistor connected in parallel with the first switch; a second attenuation circuit, connected between the second switch part and the ground, and comprising a second switch and a resistor connected in parallel with the second switch; and a switch control circuit configured to control the first series switch, the first shunt switch, the second series switch, the second shunt switch, the first attenuation circuit, and the second attenuation circuit based on a first control signal, and select one of a first signal path between the first input port and the output port, and a second signal path between the second input port and the output port based on a second control signal, wherein the first control signal is determined based on a magnitude of a signal transmitted to the output port.

Other features and aspects will be apparent from the following detailed description, the drawings, and the claims.

### BRIEF DESCRIPTION OF DRAWINGS

FIG. 1 illustrates a diagram of an example RF switch circuit, in accordance with one or more embodiments.

FIG. 2 illustrates a diagram of an example of the first attenuation circuit 130 illustrated in FIG. 1.

FIG. 3 illustrates a diagram of an example of the second attenuation circuit 140 illustrated in FIG. 1.

FIG. 4 is a diagram illustrating a method of controlling switches based on a control signal VC0 and a control signal VC1 in a switch control circuit, in accordance with one or more embodiments.

FIG. 5 is a diagram illustrating a detector shown in FIG. 1.

FIG. 6 is a diagram illustrating attenuation of an output RF signal when the control signal VC0 is 1 and the control signal VC1 is 0.

FIG. 7 is a diagram illustrating attenuation of an output RF signal when the control signal VC0 is 1 and the control signal VC1 is 1.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein.

However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

Throughout the specification, a radio frequency (RF) signal may have a format according to other random wireless and wired protocols designated by, as only examples, Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

One or more examples may provide an RF switch circuit that prevents a signal of excessive magnitude exceeding an operating range of the power amplifier from being passed to the power amplifier.

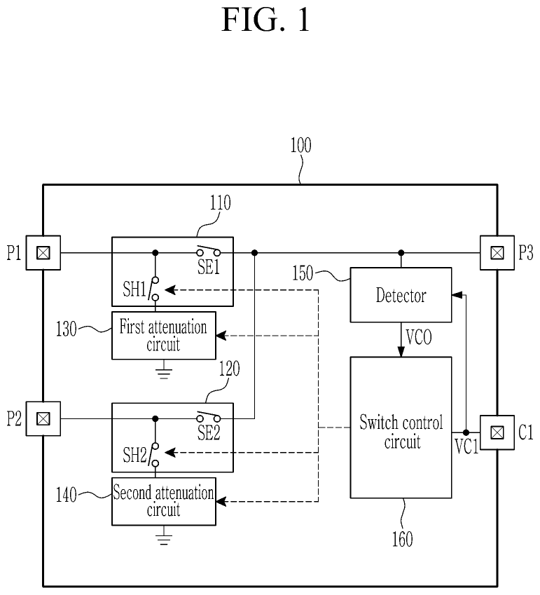

FIG. 1 illustrates a diagram of an example RF switch circuit, in accordance with one or more embodiments.

Referring to FIG. 1, the example RF switch circuit 100 includes a first port P1, a second port P2, a third port P3, a control port C1, a first switch part 110, a second switch part 120, a first attenuation circuit 130, a second attenuation circuit 140, a detector 150 and a switch control circuit 160.

In an example, the first port P1 and the second port P2 may be input ports. RF signals of different frequency bands may be input to the first port P1 and the second port P2, respectively.

In an example, an RF signal that is based on a communication method of a 2nd generation communication system may be input to the first port P1, and an RF signal that is based on a communication method of a 3rd or 4th generation communication system may be input to the second port P2.

In an example, the third port P3 may be an output port. The RF signal input through the first port P1 or the second port P2 may be output through the third port P3. In an example, a power amplifier may be connected to the third port P3.

The first switch part 110 may include a series switch SE1 and a shunt switch SH1. The series switch SE1 may be connected between the first port P1 and the third port P3. The shunt switch SH1 may be connected between the first port P1 and the ground. The series switch SE1 and the shunt switch SH1 may operate complementary. When the series switch SE1 is turned on, the shunt switch SH1 may be turned off, and when the series switch SE1 is turned off, the shunt switch SH1 may be turned on.

The second switch part 120 may include a series switch SE2 and a shunt switch SH2. The series switch SE2 may be connected between the second port P2 and the third port P3. The shunt switch SH2 may be connected between the second port P2 and the ground. The series switch SE2 and the shunt switch SH2 may operate complementary. When the series switch SE2 is turned on, the shunt switch SH2 may be turned off, and when the series switch SE2 is turned off, the shunt switch SH2 may be turned on.

The series switch SE1, the series switch SE2, the shunt switch SH1, and the shunt switch SH2 may be turned on or turned off based on a control signal output from the switch control circuit 160. When the series switch SE1 is turned on, a signal path between the first port P1 and the third port P3 may be selected, and the RF signal input through the first port P1 may be passed to the power amplifier through the third port P3. When the series switch SE2 is turned on, a signal path between the second port P2 and the third port P3 may be selected, and the RF signal input through the second port P2 may be passed to the power amplifier through the third port P3.

If the RF switch circuit 100 outputs the RF signal input through the first port P1 to the third port P3, the series switch SE1 may be turned on and the series switch SE2 may be turned off. At this time, in order to increase isolation of the RF signal between the first port P1 and the third port P3, the shunt switch SH1 may be turned off and the shunt switch SH2 may be turned on.

If the RF switch circuit 100 outputs the RF signal input through the second port P2 to the third port P3, the series switch SE2 may be turned on and the series switch SE1 may be turned off. At this time, in order to increase isolation of the RF signal between the second port P2 and the third port P3, the shunt switch SH2 may be turned off and the shunt switch SH1 may be turned on.

The first attenuation circuit 130 may be connected between the shunt switch SH1 and the ground. The first attenuation circuit 130 may operate under the control of the switch control circuit 160 and attenuate the magnitude of the RF signal output from the first port P1 to the third port P3 during operation.

The second attenuation circuit 140 may be connected between the shunt switch SH2 and the ground. The second attenuation circuit 140 may operate under the control of the switch control circuit 160, and may attenuate the magnitude of an RF signal output from the second port P2 to the third port P3 during operation.

The detector 150 may detect the magnitude of the RF signal output to the third port P3. The detector 150 may generate the control signal VC0 based on the magnitude of the RF signal output to the third port P3. In an example, the detector 150 may output 1 as the control signal VC0 when the magnitude of the RF signal is greater than or equal to a predetermined level, and output 0 as the control signal VC0 when the magnitude of the RF signal is less than the predetermined level. The detector 150 may output the control signal VC0 to the switch control circuit 160.

The switch control circuit 160 may control the series switch SE1 and the shunt switch SH1 of the first switch part 110, the series switch SE2 and the shunt switch SH2 of the second switch part 120, the first attenuation circuit 130, and the second attenuation circuit 140, based on the control signal VC0 output from the detector 150 and the control signal VC1 input through the control port C1.

The control signal VC1 may be a signal to select one signal path among a signal path between the first port P1 and the third port P3, and a signal path between the second port P2 and the third port P3.

In an example, there are the first port P1 and the second port P2 which are illustrated as input ports, and RF signals of different frequency bands may be input to the first port P1 and the second port P2. At this time, the RF signal input through the first port P1 or the second port P2 may be output to the third port P3 according to the control signal VC1. In an example, when the control signal VC1 is 0, the RF signal input through the first port P1 may be selected and output to the third port P3. If the control signal VC1 is 1, an RF signal input through the second port P2 may be selected and output to the third port P3. Although only two input ports P1 and P2 are illustrated in FIG. 1, this is only an example, and less or more ports may be implemented based on the intended operations.

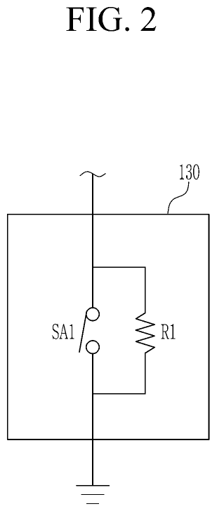

FIG. 2 is a diagram illustrating an example of the first attenuation circuit 130 illustrated in FIG. 1.

Referring to FIG. 2, the first attenuation circuit 130 may include a switch SA1 and a resistor R1.

The switch SA1 may be connected between the shunt switch SH1 and the ground.

The resistor R1 may be connected between shunt switch SH1 and ground. That is, the resistor R1 may be connected between both ends of the switch SA1.

The switch SA1 may be turned on or off according to the control of the switch control circuit 160.

In an example, when the series switch SE1 is turned on and the shunt switch SH1 is turned on and the switch SA1 is turned off under the control of the switch control circuit 160, the RF signal input through the first port P1 may be passed to the third port P3 through the series switch SE1, and at the same time may be passed to the ground through the shunt switch SH1 and the resistor R1. As such, as the RF signal input through the first port P1 is divided into two paths, the magnitude of the RF signal output to the third port P3 may be attenuated.

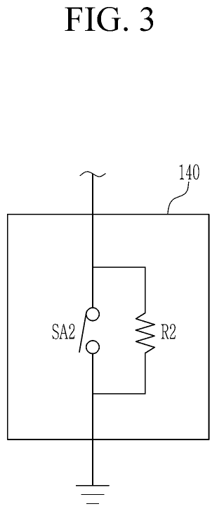

FIG. 3 is a diagram illustrating an example of the second attenuation circuit 140 illustrated in FIG. 1.

Referring to FIG. 3, the second attenuation circuit 140 may include a switch SA2 and a resistor R2.

The switch SA2 may be connected between shunt switch SH2 and ground.

The resistor R2 may be connected between shunt switch SH2 and ground. That is, the resistor R2 may be connected between both ends of the switch SA2.

The switch SA2 may be turned on or off according to the control of the switch control circuit 160.

In an example, when the series switch SE2 is turned on and the shunt switch SH2 is turned on and the switch SA2 is turned off under the control of the switch control circuit 160, the RF signal input through the series switch SE2 may be passed to the third port P3 through the series switch SE2, and at the same time may be passed to the ground through the shunt switch SH2 and the resistor R2. Accordingly, as the RF signal input through the second port P2 is divided into two paths, the magnitude of the RF signal output to the third port P3 may be attenuated.

The attenuation circuits 130 and 140 shown in FIGS. 2 and 3 are one example, and may be composed of a combination of a resistor, an inductor, and a capacitor, as only examples, instead of the resistors R1 and R2.

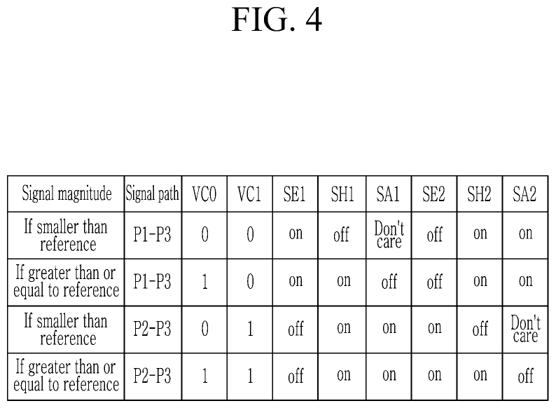

FIG. 4 is a diagram illustrating a method of controlling switches based on a control signal VC0 and a control signal VC1 in a switch control circuit, in accordance with one or more embodiments.

Referring to FIG. 4, when the control signal VC1 is 0, a signal path between the first port P1 and the third port P3 may be selected. That is, the RF signal input through the first port P1 may be selected and output to the third port P3.

If the control signal VC1 is 1, a signal path between the second port P2 and the third port P3 can be selected. That is, the RF signal input through the second port P2 may be selected and output to the third port P3.

The detector 150 may output 1 as the control signal VC0 if the magnitude of the RF signal output through the third port P3 is greater than or equal to a predetermined reference value, and output 0 as the control signal VC0 if the magnitude of the RF signal output through the third port P3 is less than the predetermined reference value.

The switch control circuit 160 may determine on or off states of the series switch SE1 and the shunt switch SH1 of the first switch part 110, the series switch SE2 and the shunt switch SH2 of the second switch part 120, the switch SA1 of the first attenuation circuit 130 and the switch SA2 of the second attenuation circuit 140 using the control signal VC0 and the control signal VC1.

The switch control circuit 160 may determine whether to attenuate the magnitude of the RF signal output to the third port P3 according to the control signal VC0. The switch control circuit 160 may determine to attenuate the magnitude of the RF signal output through the third port P3 if the control signal VC0 is 1. In an example, if the control signal VC0 is 0, there is no need to attenuate the RF signal output through the third port P3.

The switch control circuit 160 may control the on or off states of the series switch SE1 of the first switch part 110 and the series switch SE2 of the second switch part 120 based on the control signal VC1. The switch control circuit 160 may control on or off states of the shunt switch SH1 of the first switch part 110, the shunt switch SH2 of the second switch part 120, the switch SA1 of the first attenuation circuit 130 and the switch SA2 of the second attenuation circuit 140 based on the control signal VC1, if the control signal VC0 is 0, that is, if the magnitude of the RF signal output to the third port P3 is smaller than the predetermined reference value.

If the control signal VC0 is 0 and the control signal VC1 is 0, the switch control circuit 160 may set the series switch SE1 of the first switch part 110 to an on state, the shunt switch SH1 of the first switch part 110 to an off state, the series switch SE2 of the second switch part 120 to an off state and the shunt switch SH2 of the second switch part 120 to an on state. Accordingly, since the shunt switch SH1 is in an off state and the control signal VC0 is 0, the switch control circuit 160 may set the switch SA1 of the first attenuation circuit 130 to an arbitrary state (don't care). Additionally, since the shunt switch SH2 is in an on state and the control signal VC0 is 0, the switch control circuit 160 may set the switch SA2 of the second attenuation circuit 140 to an on state, so that the isolation of the RF signal between the first port P1 and the third port P3 may be increased.

If the control signal VC1 is 1 and the control signal VC0 is 0, the switch control circuit 160 may set the series switch SE2 of the second switch part 120 to an on state, the shunt switch SH2 to an off state, the series switch SE1 of the first switch part 110 to an off state and the shunt switch SH1 to an on state. Accordingly, since the shunt switch SH2 is off and the control signal VC0 is 0, the switch control circuit 160 may set the switch SA2 of the second attenuation circuit 140 to an arbitrary state (don't care). Additionally, since the shunt switch SH1 is in an on state and the control signal VC0 is 0, the switch control circuit 160 may set the switch SA1 of the first attenuation circuit 130 to an on state. By doing this, it is possible to increase the isolation of the RF signal between the second port P2 and the third port P3.

As such, if the control signal VC0 is 0, the switch control circuit 160 may determine on or off states of the series switch SE1 and the shunt switch SH1 of the first switch part 110 and the series switch SE2 and the shunt switch SH2 of the second switch part 120 based on the control signal VC1. However, if the control signal VC0 is 1, an operation to attenuate the magnitude of the RF signal may be desired. If the control signal VC0 is 1 and the control signal VC1 is 0, the attenuation operation of the first attenuation circuit 130 may be desired, and if the control signal VC0 is 1 and the control signal VC1 is 1, the attenuation operation of the second attenuation circuit 140 may be desired.

The switch control circuit 160 may control on or off states of the shunt switch SH1 of the first switch part 110, the shunt switch SH2 of the second switch part 120, the switch SA1 of the first attenuation circuit 130 and the switch SA2 of the second attenuation circuit 140 based on the control signal VC0 and the control signal VC1, if the control signal VC0 is 1, that is, if the magnitude of the RF signal output to the third port P3 is greater than or equal to the predetermined reference value.

If the control signal VC0 is 1, the switch control circuit 160 may determine on or off states of the series switch SE1 of the first switch part 110 and the series switch SE2 of the second switch part 120 based on the control signal VC1. If the control signal VC1 is 0, the switch control circuit 160 may set the series switch SE1 of the first switch part 110 to an on state and the series switch SE2 of the second switch part 120 to an off state. Accordingly, if the control signal VC0 is 1, since the attenuation operation of the first attenuation circuit 130 may be desired, the switch control circuit 160 may set the shunt switch SH1 of the first switch part 110 to an on state and the switch SA1 of the first attenuation circuit 130 to an off state. Since the attenuation operation of the second attenuation circuit 140 may be not desired, the switch control circuit 160 may set the shunt switch SH2 of the second switch part 120 to an on state and set the switch SA2 of the second attenuation circuit 140 to an on state based on the control signal VC1, so that the isolation of the RF signal between the first port P1 and the third port P3 may be increased.

Additionally, if the control signal VC1 is 1, the switch control circuit 160 may set the series switch SE2 of the second switch part 120 to an on state and set the series switch SE1 of the first switch part 110 to an off state. Accordingly, if the control signal VC0 is 1, since the attenuation operation of the second attenuation circuit 140 may be desired, the switch control circuit 160 may set the shunt switch SH2 of the second switch part 120 to an on state and set the switch SA2 of the second attenuation circuit 140 to an off state. Since the attenuation operation of the first attenuation circuit 130 may not be desired, the switch control circuit 160 may set the shunt switch SH1 of the first switch part 110 to an on state and set the switch SA1 of the first attenuation circuit 130 to an on state based on the control signal VC1, so that the isolation of the RF signal between the second port P2 and the third port P3 may be increased.

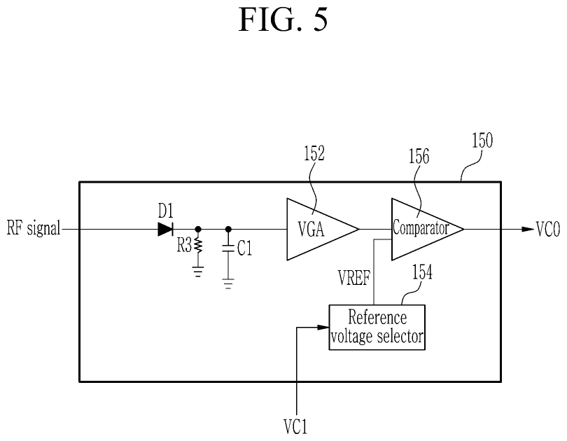

FIG. 5 is a diagram illustrating an example detector illustrated in FIG. 1.

Referring to FIG. 5, the detector 150 may include a diode D1, a resistor R3, a capacitor C1, a variable gain amplifier (VGA) 152, a reference voltage selector 154, and a comparator 156.

The RF signal output through the third port P3 may be rectified and converted into a DC voltage signal through the diode D1, the resistor R3, and the capacitor C1.

The DC voltage signal for the RF signal output through the third port P3 may be transferred to the VGA 152.

The VGA 152 may amplify the DC voltage signal to a desired magnitude and output the amplified signal to the comparator 156.

The reference voltage selector 154 may select the reference voltage VREF based on the control signal VC1. The reference voltage VREF may be a voltage that is used as a reference for comparison with a voltage input from the comparator 156.

RF signals of different frequency bands may be respectively input to the first port P1 and the second port P2. For example, 2nd generation, 3rd generation, 4th generation, and 5th generation communication systems may use different frequency bands, and have different RF signal magnitudes and different modulation schemes according to communication methods. Therefore, the comparator 156 should use different reference voltages according to the type of input RF signal. The reference voltage selector 154 may select the reference voltage VREF according to the value of the control signal VC1, and provide the selected reference voltage VREF to the comparator 156.

As an example of a method for selecting the reference voltage VREF in the reference voltage selector 154, the reference voltage selector 154 may store the reference voltages VREF corresponding to the values of the control signal VC1, respectively, and select the reference voltage VREF corresponding to a value of the control signal VC1. The reference voltage selector 154 may store the reference voltages VREF corresponding to the values of the control signal VC1 as a table in the form of Table 1.

TABLE 1

| Communication | Input | Output | | RF Power | |
|---|---|---|---|---|---|
| method | port | port | VC1 | (max.) | VREF |
| 2 G | P1 | P3 | 0 | 10 dBm | 0.5 V |
| 3 G/4 G | P2 | | 1 | 15 dBm | 1.0 V |

In Table 1, it is shown that the RF signal according to the communication method of the 2nd generation communication system may be input through the first port P1, and the RF signal according to the communication method of the 3rd or 4th generation communication system may be input through the second port P2. VC1=0 may mean signal path selection between the first port P1 and the third port P3, and VC1=1 may mean signal path selection between the second port P2 and the third port P3.

Accordingly, the reference voltage VREF used in the comparator 156 may be selected by the reference voltage selector 154 to have a different value according to the control signal VC1.

The comparator 156 may compare the voltage output from the VGA 152 with the reference voltage VREF, and generate a control signal VC0 based on the comparison result. In an example, the comparator 156 may output a control signal VC0 having a value of 0 if the voltage output from the VGA 152, that is, the voltage corresponding to the magnitude of the RF signal output to the third port P3, is smaller than the reference voltage VREF. Furthermore, the comparator 156 may output a control signal VC0 having a value of 1 if the voltage corresponding to the magnitude of the RF signal output to the third port P3 is greater than or equal to the reference voltage VREF.

The comparator 156 may output the control signal VC0 to the switch control circuit 160.

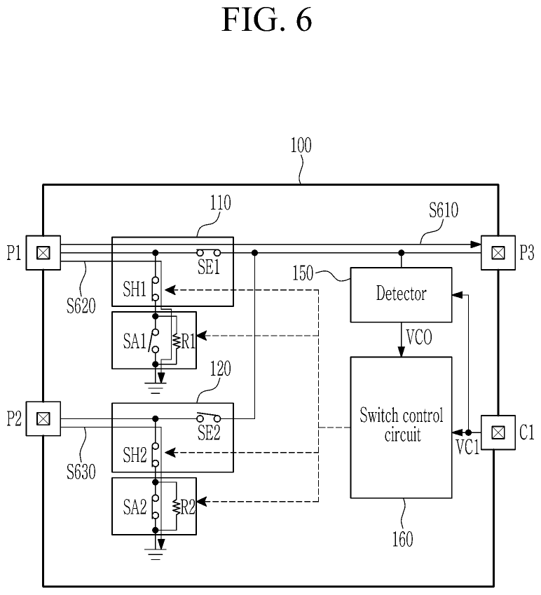

FIG. 6 is a diagram illustrating attenuation of an output RF signal when the control signal VC0 is 1 and the control signal VC1 is 0.

Referring to FIG. 6, if the control signal VC1 is 0 and the control signal VC0 is 1, the series switch SE1 of the first switch part 110 may be turned on, the series switch SE2 of the second switch part 120 may be turned off, the shunt switch SH1 of the first switch part 110 may be turned on, and the switch SA1 of the first attenuation circuit 130 may be turned off. Then, the RF signal input to the first port P1 may be divided into a path S610 toward the third port P3 through the series switch SE1 and a path S620 toward the ground through the shunt switch SH1 and resistor R1. At this time, the ratio at which the RF signal input to the first port P1 is divided into the two paths S610 and S620 may be determined by the impedance of the first attenuation circuit 130. In an example, the impedance of the first attenuation circuit 130 may correspond to the resistance value of the resistor R1. By doing this, the magnitude of the RF signal output from the first port P1 to the third port P3 may be attenuated corresponding to the resistance value of the resistor R1.

Additionally, when the control signal VC1 is 0 and the control signal VC0 is 1, the shunt switch SH2 of the second switch part 120 may be turned on and the switch SA2 of the second attenuation circuit 140 may be turned on. That is, if the first switch part 110 performs a signal transmission operation, the second switch part 120 may be turned off. At this time, the shunt switch SH2 of the second switch part 120 and the switch SA2 of the second attenuation circuit 140 may be turned on, the RF signal of the second port P2 may be transmitted to a path S630 toward the ground through the shunt switch SH2 of the second switch part 120 and the switch SA2 of the second attenuation circuit 140. Accordingly, the isolation of RF signals between the first port P1 and the third port P3 may be increased.

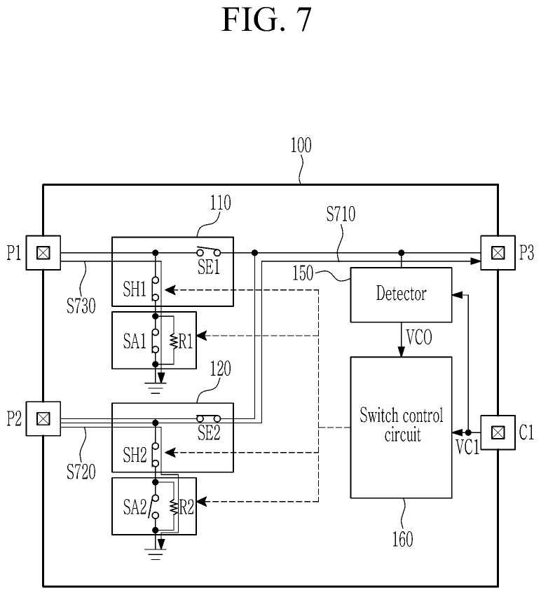

FIG. 7 is a diagram illustrating attenuation of an output RF signal when the control signal VC0 is 1 and the control signal VC1 is 1.

Referring to FIG. 7, if the control signal VC1 is 1 and the control signal VC0 is 1, the series switch SE2 of the second switch part 120 may be turned on, and the series switch SE1 of the first switch part 110 may be turned off, the shunt switch SH2 of the second switch part 120 may be turned on, and the switch SA2 of the second attenuation circuit 140 may be turned off. Then, the RF signal input to the second port P2 may be divided into a path S710 toward the third port P3 through the series switch SE2 and a path S720 toward the ground through the shunt switch SH2 and resistor R2. At this time, the ratio at which the RF signal input to the second port P2 is divided into two paths S710 and S720 may be determined by the impedance of the second attenuation circuit 140. In an example, the impedance of the second attenuation circuit 140 may correspond to the resistance value of the resistor R2. By doing this, the magnitude of the RF signal output from the second port P2 to the third port P3 may be attenuated corresponding to the resistance value of the resistor R2.

Additionally, if the control signal VC1 is 1 and the control signal VC0 is 1, the shunt switch SH1 of the first switch part 110 may be turned on and the switch SA1 of the first attenuation circuit 130 may be turned on. That is, if the second switch part 120 performs a signal transmission operation, the first switch part 110 may be turned off. At this time, the shunt switch SH1 of the first switch part 110 and the switch SA1 of the first attenuation circuit 130 may be turned on, the RF signal of the first port P1 may be transmitted to a path S730 toward the ground through the shunt switch SH1 of the first switch part 110 and the switch SA1 of the first attenuation circuit 130. Accordingly, the isolation of RF signals between the second port P2 and the third port P3 may be increased.

According to at least one example, since a signal having a certain magnitude or more may be attenuated and input to the power amplifier, the over voltage protection (OVP) or over current protection (OCP) circuit inside the power amplifier may be removed, and the performance of the power amplifier may be improved, through the removal of the OVP or OCP circuit.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A radio frequency (RF) switch circuit configured to output a first signal input through a first input port to an output port, and configured to output a second signal input through a second input port to the output port, the RF switch circuit comprising:
a first series switch configured to output the first signal input through the first input port to the output port;
a first shunt switch connected to the first input port;
a first attenuation circuit connected between the first shunt switch and a ground, and configured to attenuate the first signal output from the first input port to the output port;
a detector configured to detect a magnitude of one of the first signal and the second signal output to the output port, and generate a first control signal based on the magnitude of the detected signal; and
a switch control circuit configured to control the first series switch, the first shunt switch, and the first attenuation circuit based on the first control signal and a second control signal to select a first signal path between the first input port and the output port.

2. The RF switch circuit of claim 1, wherein:
the first attenuation circuit comprises:
a first switch connected between the first shunt switch and the ground; and
a first resistor connected between the first shunt switch and the ground,
wherein the switch control circuit is configured to determine a turn-on operation or a turn-off operation of the first series switch, the first shunt switch, and the first switch based on the first control signal and the second control signal.

3. The RF switch circuit of claim 2, further comprising:
a second series switch configured to output the signal input through the second input port to the third port;
a second shunt switch connected to the second input port; and
a second attenuation circuit connected between the second shunt switch and the ground and configured to attenuate the signal output from the second input port to the output port,
wherein the switch control circuit is configured to select the first signal path between the first input port and the output port or a second signal path between the second input port and the output port based on a value of the second control signal, and control the second series switch, the second shunt switch, and the second attenuation circuit based on the first control signal and the second control signal.

4. The RF switch circuit of claim 3, wherein:
the second attenuation circuit comprises:
a second switch connected between the second shunt switch and the ground; and
a second resistor connected between the second shunt switch and the ground,
wherein the switch control circuit is configured to determine a turn-on operation or a turn-off operation of the second series switch, the second shunt switch, and the second switch based on the first control signal and the second control signal.

5. The RF switch circuit of claim 2, wherein:
the detector comprises:
a reference voltage selector configured to select a reference voltage based on the second control signal; and
a comparator configured to compare a first voltage corresponding to a magnitude of the first signal or the second signal output to the output port with the reference voltage, and generate the first control signal to have a first value when the first voltage is less than the reference voltage, and to have a second value when the first voltage is greater than or equal to the reference voltage.

6. The RF switch circuit of claim 5, wherein:
the second control signal has a first value indicating signal path selection between the first input port and the output port, and a second value indicating signal path selection between the second input port and the output port, and
the reference voltage selector is configured to store different reference voltages respectively corresponding to the first value of the second control signal and the second value of the second control signal, and provide the selected reference voltage corresponding to the value of the input second control signal to the comparator.

7. The RF switch circuit of claim 6, wherein:
when the second control signal has the first value and the first control signal has the second value, the switch control circuit is configured to control the first series switch to be in a turned on state, control the second series switch to be in a turned off state, control the first shunt switch, the second shunt switch, and the second switch to be in a turned on state, and control the first switch to be in a turned off state.

8. The RF switch circuit of claim 6, wherein:
when the second control signal has the second value and the first control signal has the second value, the switch control circuit is configured to control the second series switch to be in a turned on state, control the first series switch to be in a turned off state, control the first shunt switch, the second shunt switch, and the first switch to be in a turned on state, and control the second switch to be in a turned off state.

9. The RF switch circuit of claim 6, wherein:
when the second control signal has the first value and the first control signal has the first value, the switch control circuit is configured to control the first series switch to be in a turned on state, control the second series switch to be in a turned off state, control the first shunt switch to be in a turned off state, and control the second shunt switch and the second switch to be in a turned on state.

10. The RF switch circuit of claim 6, wherein:
when the second control signal has the second value and the first control signal has the first value, the switch control circuit is configured to control the second series switch to be in a turned on state, control the first series switch to be in a turned off state, control the second shunt switch to be in a turned off state, and control the first shunt switch and the first switch to be in a turned on state.

11. A radio frequency (RF) switch, comprising:
a first input port configured to receive a first signal;
a second input port configured to receive a second signal;
an output port;
a first switch part configured to output the first signal to the output port;
a second switch part configured to output the second signal to the output port;
a first attenuation circuit configured to attenuate the first signal output to the output port;
a second attenuation circuit configured to attenuate the second signal output to the output port;
a detector configured to detect a magnitude of one of the first signal and the second signal output to the output port and generate a first control signal based on the magnitude of the detected signal; and
a switch control circuit configured to control the first switch part, the second switch part, the first attenuation circuit, and the second attenuation circuit based on the first control signal and a second control signal to select one of a first signal path between the first input port and the output port, and a second signal path between the second input port and the output port.

12. The RF switch circuit of claim 11, wherein:
the first switch part comprises:
a first series switch connected between the first input port and the output port; and
a first shunt switch connected between the first input port and a ground, the second switch part comprises:
a second series switch connected between the second input port and the output port; and
a second shunt switch connected between the second input port and the ground, the first attenuation circuit comprises:
a first switch connected between the first shunt switch and the ground; and
a first resistor connected between the first shunt switch and the ground, and the second attenuation circuit comprises:
a second switch connected between the second shunt switch and the ground; and
a second resistor coupled between the second shunt switch and the ground.

13. The RF switch circuit of claim 12, wherein:
the detector comprises:
a reference voltage selector configured to select a reference voltage based on the second control signal; and
a comparator configured to generate the first control signal to have a first value when a first voltage corresponding to the magnitude of the one of the first signal and the second signal output to the output port is less than the reference voltage, and to have a second value when the first voltage is greater than or equal to the reference voltage.

14. The RF switch circuit of claim 13, wherein:
the second control signal has a first value to select the first signal path and a second value to select the second signal path, and
the reference voltage selector is configured to select the reference voltage when the second control signal has a first value, and is configured to select the reference voltage when the second control signal has a second value different from the first value, and provide the selected reference voltage to the comparator.

15. The RF switch circuit of claim 12, wherein:
the switch control circuit is configured to control a turn-on operation or a turn-off operation of the first series switch and the second series switch based on the value of the second control signal, and control a turn-on operation or a turn-off operation of the first shunt switch, the second shunt switch, the first switch, and the second switch based on the value of the first control signal and the value of the second control signal,
the second control signal has a first value to select the first signal path and a second value to select the second signal path, and
the first control signal has a first value and a second value different from the first value based on the magnitude of the signal output to the output port.

16. A radio frequency (RF) switch, comprising:
a first input port;
a second input port;
an output port;
a first switch part, including a first series switch and a first shunt switch, and configured to receive a first signal from the first input port;
a second switch part, including a second series switch and a second shunt switch, and configured to receive a second signal from the second input port;
a first attenuation circuit, connected between the first switch part and a ground, and comprising a first switch and a resistor connected in parallel with the first switch;
a second attenuation circuit, connected between the second switch part and the ground, and comprising a second switch and a resistor connected in parallel with the second switch; and
a switch control circuit configured to control the first series switch, the first shunt switch, the second series switch, the second shunt switch, the first attenuation circuit, and the second attenuation circuit based on a first control signal, and select one of a first signal path between the first input port and the output port, and a second signal path between the second input port and the output port based on a second control signal,
wherein the first control signal is determined based on a magnitude of a signal transmitted to the output port.
